(19) United States
(12) Patent Application Publication
(10) Pub. No.: US 2026/0362995 A1
(43) Pub. Date: Nov. 12, 2026

(54) MANUFACTURING METHOD OF SEMICONDUCTOR STRUCTURE

(71) Applicant: NANYA TECHNOLOGY CORPORATION, New Taipei City (TW)

(72) Inventors: Jin-Sheng LIOU, New Taipei City (TW); Dan-Chieh CHIU, New Taipei City (TW); Chen-Hao LIEN, New Taipei City (TW)

(21) Appl. No.: 19/201,961

(22) Filed: May 8, 2025

(51) Int. Cl. H10P 30/40; H10P 50/00; H10P 50/26; H10P 50/28

(52) U.S. Cl. CPC H10P 30/40; H10P 50/266; H10P 50/283; H10P 50/71; H10P 50/73

(57) ABSTRACT

A method of manufacturing semiconductor structure is provided. The method includes following steps. A substrate is provided. A conductive layer is formed on the substrate. A dielectric layer is formed on the conductive layer. A hard mask layer is formed on the dielectric layer, wherein the hard mask layer includes carbon. An implantation process is performed to implant nitrogen into the hard mask layer to form an implanted hard mask layer. A trench is formed by removing a portion of the implanted hard mask layer, the dielectric layer and the conductive layer. The implanted hard mask layer is removed to expose the top surface of the dielectric layer, wherein the dielectric layer and the conductive layer collectively form a bit line structure in which a sidewall of the bit line structure is a vertical sidewall.

### BACKGROUND

### Field of Invention

The present disclosure relates to a manufacturing method of a semiconductor structure.

### Description of Related Art

In recent decades, demand to storage capability has increased as electronic products continue to improve. In order to increase storage capability of a memory device (e.g., a DRAM device), more memory cells are integrated in the memory device. As the integration level increases, the wiggling problem of bit line may increase.

### SUMMARY

In accordance with an aspect of the present disclosure, a method of manufacturing semiconductor structure is provided. The method includes following steps. A substrate is provided. A conductive layer is formed on the substrate. A dielectric layer is formed on the conductive layer. A hard mask layer is formed on the dielectric layer, wherein the hard mask layer includes carbon. An implantation process is performed to implant nitrogen into the hard mask layer to form an implanted hard mask layer, wherein the implantation process is performed under a nitrogen dose of 1×10¹⁷ N⁺/cm² to 5×10¹⁷ N⁺/cm² and an implantation temperature of −200 °C to 600 °C. A trench is formed by removing a portion of the implanted hard mask layer, the dielectric layer and the conductive layer such that a top surface of the substrate is exposed, wherein a first angle between a top surface and a sidewall of the implanted hard mask remained 90 degree after forming a trench. The implanted hard mask layer is removed to expose the top surface of the dielectric layer, wherein the dielectric layer and the conductive layer collectively form a bit line structure in which a sidewall of the bit line structure is a vertical sidewall.

According to some embodiments of the present disclosure, the method further comprises after performing the implantation process, forming a first dielectric layer on the implanted hard mask layer, and forming a second dielectric layer on the first additional mask, wherein the first additional mask and the second additional mask comprise different materials.

According to some embodiments of the present disclosure, wherein forming the dielectric layer comprises forming a first dielectric layer on the conductive layer and forming a second dielectric layer on the first dielectric layer, wherein the first dielectric layer and the second dielectric layer comprise different materials.

According to some embodiments of the present disclosure, wherein the trench is formed by performing a dry etching process with CHF₃ and Ar at 15 °C.

According to some embodiments of the present disclosure, wherein the implantation process is performed under the implantation temperature of −100 °C.

According to some embodiments of the present disclosure, wherein the implantation process is performed under the nitrogen dose 2×10¹⁷ N⁺/cm².

According to some embodiments of the present disclosure, wherein the implantation process is performed under an implantation voltage of 100 keV.

According to some embodiments of the present disclosure, the method further comprises forming a spacer on the sidewall of the bit line structure.

In accordance with an aspect of the present disclosure, a method of manufacturing semiconductor structure is provided. The method includes following steps. A substrate is provided. A conductive layer is formed on the substrate. A dielectric layer is formed on the conductive layer. A hard mask layer is formed on the dielectric layer, wherein the hard mask layer comprises SP²-bonded carbon and hydrogen hexagonal planar structure. An implantation process is performed to implant nitrogen into the hard mask layer to form an implanted hard mask layer, wherein the implanted hard mask layer comprises C₃N₄ with hexagonal network of tetrahedrally bonded carbon and trigonal planar nitrogen. A trench is formed by removing a portion of the implanted hard mask layer, the dielectric layer and the conductive layer such that a top surface of the substrate is exposed, wherein a first angle between a top surface and a sidewall of the implanted hard mask remained 90 degree after forming a trench. The implanted hard mask layer is removed to expose the top surface of the dielectric layer, wherein the dielectric layer and the conductive layer collectively form a bit line structure in which a sidewall of the bit line structure is a vertical sidewall.

According to some embodiments of the present disclosure, wherein the implantation process is performed under a nitrogen dose of 1×10¹⁷ N⁺/cm² to 5×10¹⁷ N⁺/cm² and an implantation temperature of −200 °C to 600 °C.

According to some embodiments of the present disclosure, wherein the implantation process is performed under the implantation temperature of −100 °C.

According to some embodiments of the present disclosure, wherein the implantation process is performed under the nitrogen dose 2×10¹⁷ N⁺/cm².

According to some embodiments of the present disclosure, wherein the implantation process is performed under an implantation voltage of 100 keV.

According to some embodiments of the present disclosure, the method further comprises forming a spacer on the sidewall of the bit line structure.

According to some embodiments of the present disclosure, the method further comprises forming a filling layer to fill the trench.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a cross-sectional view schematic diagram of a semiconductor structure, in accordance with some embodiments;

FIG. 2 is a cross-sectional view schematic diagram of a semiconductor structure after forming a hard mask layer, in accordance with some embodiments;

FIG. 3 is a cross-sectional view schematic diagram of a semiconductor structure after performing a implantation process to form an implanted hard mask layer, in accordance with some embodiments;

FIG. 4 is a cross-sectional view schematic diagram of a semiconductor structure after forming additional masks, in accordance with some embodiments;

FIG. 5 is a cross-sectional view schematic diagram of a semiconductor structure after forming a first trench, in accordance with some embodiments;

FIG. 6 is a cross-sectional view schematic diagram of a semiconductor structure after deepen the first trench to form a second trench, in accordance with some embodiments;

FIG. 7 is a cross-sectional view schematic diagram of a semiconductor structure after removing the implanted hard mask layer, in accordance with some embodiments;

FIG. 8 is a cross-sectional view schematic diagram of a semiconductor structure after forming a spacer, in accordance with some embodiments; and

FIG. 9 is a cross-sectional view schematic diagram of a semiconductor structure after forming a filling layer, in accordance with some embodiments.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

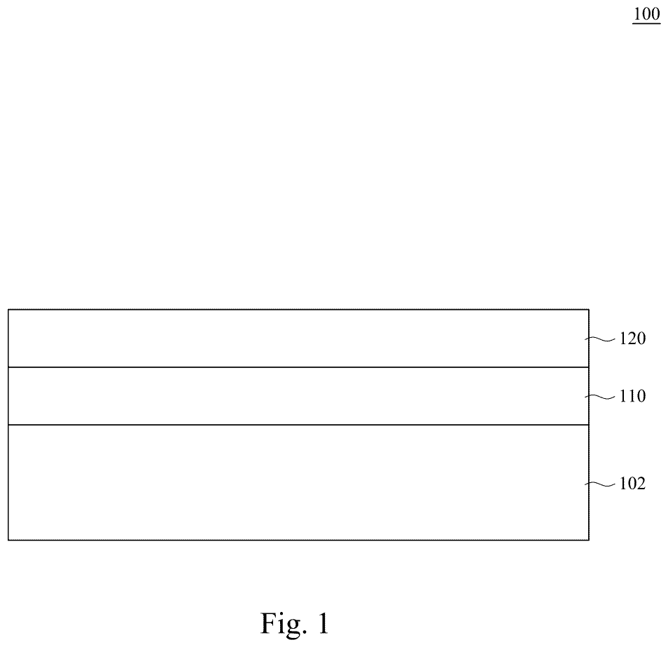

FIG. 1 to FIG. 9 are schematic diagrams of various intermediate stages in the formation of a semiconductor structure 100, in accordance with some embodiments. The semiconductor structure 100 can be applied to or part of the integrated circuit (IC), such as logic circuits, resistors, capacitors, sensors, memory device (such as dynamic random access memory (DRAM)). It should be understood that in order to simplify the graph, some components of the semiconductor structure 100 are not shown in FIG. 1 to FIG. 9, and other embodiments of the semiconductor structure 100 may include additional components.

Referring to FIG. 1, the semiconductor structure 100 includes a substrate 102. In some embodiments, the substrate 102 may be a semiconductor substrate, such as a bulk semiconductor substrate, a semiconductor-on-insulator (SOI) substrate, etc., wherein the insulator may be a buried oxide (BOX) layer, a silicon oxide layer, or the like. In some embodiments, the substrate 102 can be doped (e.g., containing p-type or n-type dopants) or undoped. In some embodiments, the semiconductor material of the substrate 102 may include silicon, germanium, compound semiconductors (including silicon carbide, gallium arsenide, gallium phosphide, indium phosphide, indium arsenide, and/or indium antimonide), alloy semiconductors or a combination thereof. The substrate 102 can also be formed of other materials, such as sapphire, indium tin oxide, and the like.

As shown in FIG. 1, a conductive layer 110 and a first dielectric layer 120 are formed on the substrate 102. In detail, the conductive layer 110 is formed between the substrate 102 and the first dielectric layer 120. In some embodiments, the conductive layer 110 may include conductive material such as metal, metal alloy, metal nitride, or the like. For example the conductive layer 110 includes tungsten. In some embodiments, the conductive layer 110 can be single layer. In other embodiments, the conductive layer 110 can be multilayer. In some embodiments, the first dielectric layer 120 may include nitride, oxide, other dielectric materials or combinations thereof. In some embodiments, the conductive layer 110 and a first dielectric layer 120 may be formed using a suitable deposition process, such as chemical vapor deposition (CVD), plasma enhanced chemical vapor deposition (PECVD), atomic layer deposition (ALD), or the like.

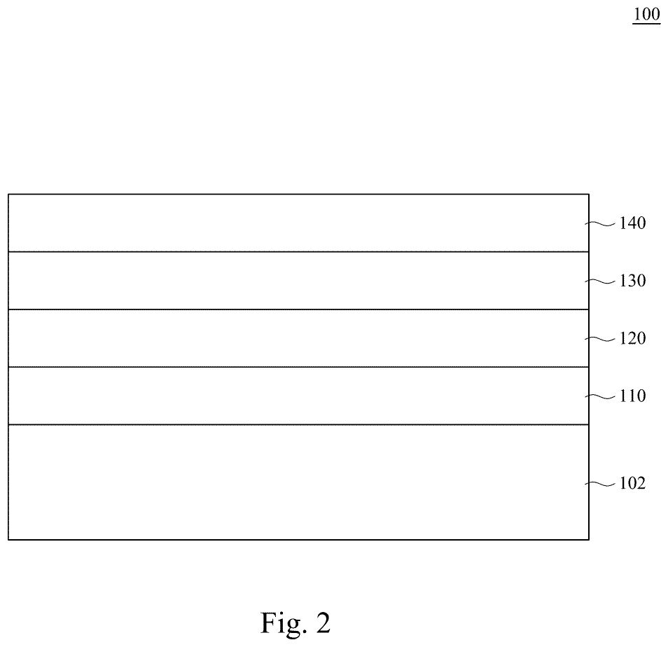

Referring to FIG. 2, a second dielectric layer 130 and a hard mask layer 140 are formed on the first dielectric layer 120. In detail, the second dielectric layer 130 is formed between the first dielectric layer 120 and the hard mask layer 140. In some embodiments, the second dielectric layer 130 may include nitride, oxide, other dielectric materials or combinations thereof. In some embodiments, the first dielectric layer 120 and the second dielectric layer 130 may include different material. In other embodiments, the first dielectric layer 120 and the second dielectric layer 130 both include nitride. In some embodiments, the hard mask layer 140 can be carbon film. For example, the hard mask layer 140 is SP²-bonded carbon and hydrogen hexagonal planar structure. In some embodiments, the second dielectric layer 130 and a hard mask layer 140 may be formed using a suitable deposition process, such as chemical vapor deposition (CVD), plasma enhanced chemical vapor deposition (PECVD), atomic layer deposition (ALD), or the like.

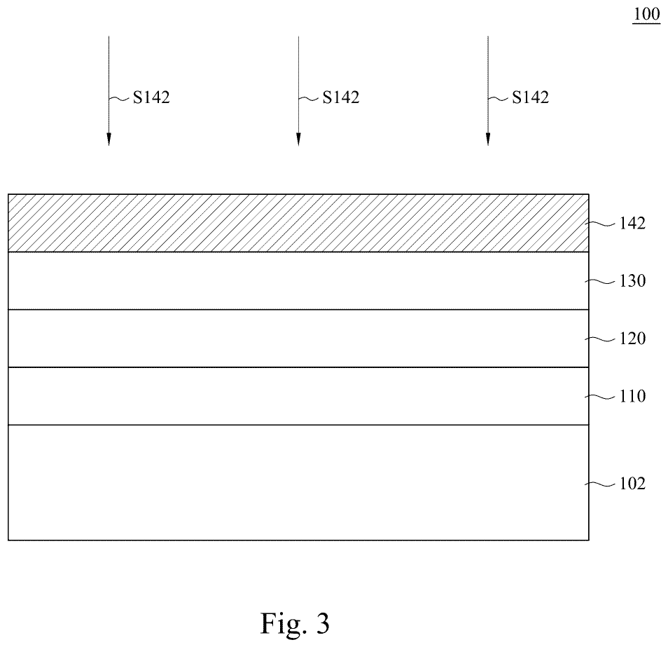

Referring to FIG. 3, an implantation process S142 is performed to transform the hard mask layer 140 into an implanted hard mask layer 142. In the implantation process S142, nitrogen is implanted into the hard mask layer 140, such that the implanted hard mask layer 142 can be C₃N₄ film. The implanted hard mask layer 142 including C₃N₄ is hexagonal network of tetrahedrally bonded carbon and trigonal planar nitrogen. In the implanted hard mask layer 142, the crystal bond properties of C₃N₄, wherein carbon and nitrogen atoms form particularly short and strong bonds in a ratio of 1:1.3 in the crystal lattice, make the material harder than the SP²-bonded carbon and hydrogen hexagonal planar structure of hard mask layer 140. The implantation process S142 can be performed under a nitrogen dose of 1×10¹⁷ N⁺/cm² to 5×10¹⁷ N⁺/cm² at an implantation voltage of 100 keV. The implantation process S142 can be performed under an implantation temperature of −200 °C to 600 °C.

Next, several tests are performed for different implantation temperatures and nitrogen implantation dose to obtain an implanted hard mask layer 142 with higher hardness. The hardness measurements can be performed using Nanoindentation (with load-displacement). The tests are performed by depositing a hard mask layer 140 (as described above) on a silicon substrate, with a thickness of about 100 nm. First, nitrogen is implanted in the hard mask layer 140 at an implantation temperature of 30 °C. The hardness test results of the implanted hard mask layer 142 formed with different nitrogen implantation doses are shown in Table 1.

TABLE 1

| Dose (×10¹⁷ N⁺/cm²) | Hardness (GPa) |
|---|---|
| 0 (no nitrogen) | 6 |
| 1 | 7.6 |
| 2 | 8.4 |
| 3 | 7.9 |
| 4 | 7.7 |
| 5 | 8 |

As shown in Table 1, when the implantation concentration is 2×10¹⁷, better hardness can be obtained. Next, nitrogen is implanted in the hard mask layer 140 at an implantation dose of 2×10¹⁷ N⁺/cm². The hardness test results of the implanted hard mask layer 142 formed at different implantation temperatures are shown in Table 2.

TABLE 2

| Temperature(°C) | Hardness (GPa) |
|---|---|
| −200 | 9 |
| −100 | 22.2 |
| −50 | 20.1 |
| 0 | 9.3 |
| 50 | 9.2 |
| 100 | 8.9 |
| 200 | 7.5 |
| 400 | 7.7 |
| 600 | 7.6 |

As the results above, the implantation process S142 is preferably performed with a nitrogen dose of 2×10¹⁷ N⁺/cm², an implantation temperature of −100 °C, and an implantation voltage of 100 keV to obtain a higher hardness (about 22.2 GPa). After the implantation process S142, as the hardness of the implanted hard mask layer 142 increases, the issue of bit line wiggling may be reduced in subsequent processes.

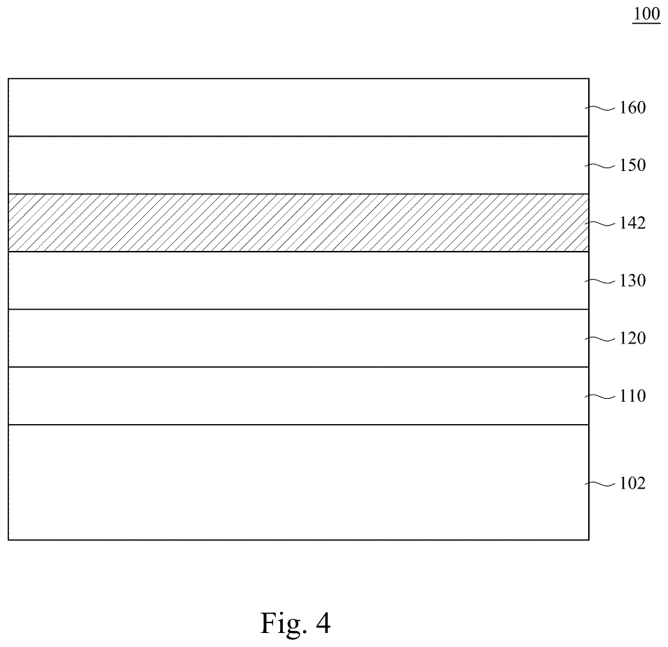

Referring to FIG. 4, a first additional mask 150 and a second additional mask 160 are formed on the implanted hard mask layer 142. In detail, the first additional mask 150 is formed between the implanted hard mask layer 142 and the second additional mask 160. In some embodiments, the first additional mask 150 and a second additional mask 160 may include silicon, other dielectric materials or combinations thereof. In some embodiments, the first additional mask 150 and the second additional mask 160 may include different material. For example, the first additional mask 150 is a silicon nitride film, and the second additional mask 160 is a silicon film. In some embodiments, it is also possible not to form the first additional mask 150 and the second additional mask 160.

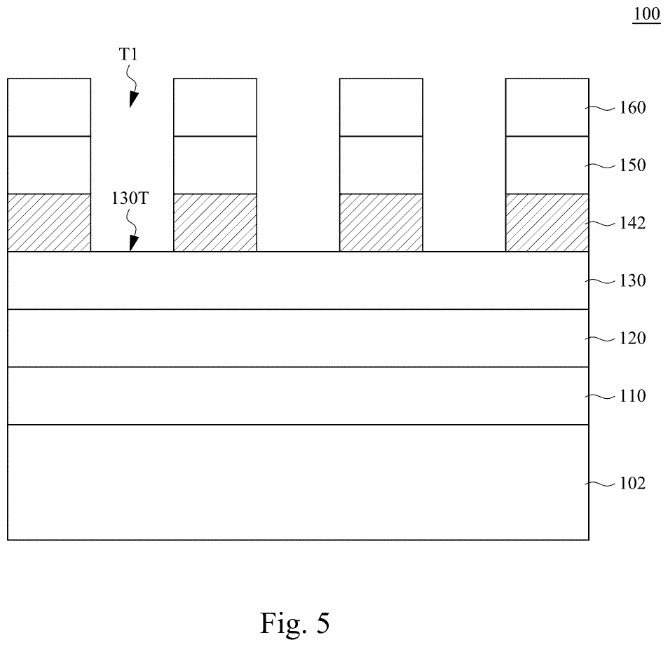

Referring to FIG. 5, a first trench T1 is formed by removing a portion of the second additional mask 160, the first additional mask 150, and the implanted hard mask layer 142. In detail, after the first trench T1 is formed, a portion of the top surface 130T of the second dielectric layer 130 is exposed. In some embodiments, the first trench T1 can be formed using a suitable directional dry etching process. For example, the dry etching process can be performed with CHF₃ (90 sccm flow), and Ar (10 sccm flow) at 15 °C.

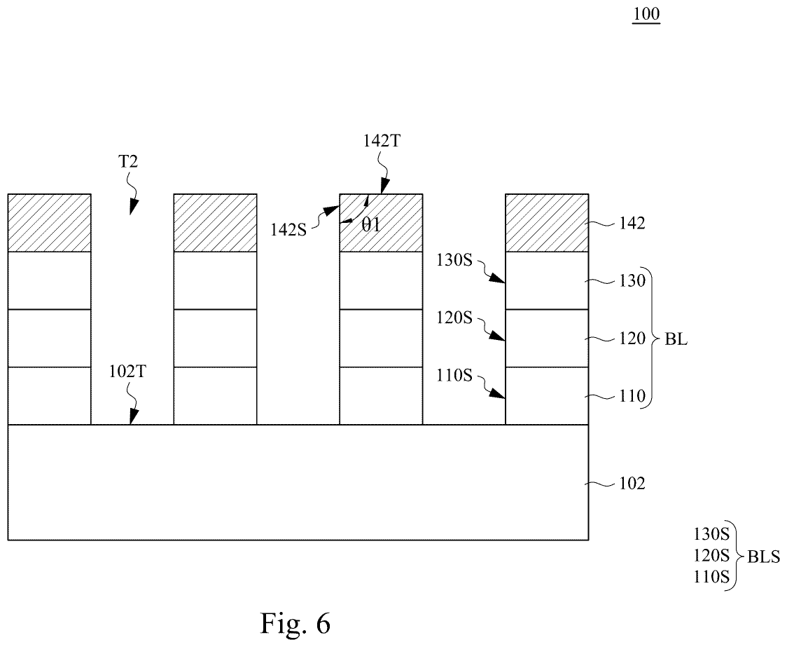

Referring to FIG. 6, the first trench T1 is deepened to form a second trench T2. In detail, after the second trench T2 is formed, a portion of the top surface 102T of the substrate 102 is exposed. In some embodiments, the second trench T2 can be formed using a suitable directional dry etching process. The first trench T1 and the second trench T2 can be formed by the same or different dry etching process. A portion of the second dielectric layer 130, the first dielectric layer 120 and the conductive layer 110 are removed when deepening the first trench T1. As shown, the first angle θ1 between the top surface 142T and the sidewall 142S of the implanted hard mask layer 142 remained about 90° after forming the second trench T2. As shown, after forming the second trench T2 the remained portion of the second dielectric layer 130, the first dielectric layer 120 and the conductive layer 110 can be bit line structure BL. The sidewall 130S of the second dielectric layer 130, the sidewall 120S of the first dielectric layer 120 and the sidewall 110S of the conductive layer 110 collectively form the sidewall BLS of the bit line BL, wherein the sidewall BLS of the bit line BL can be a vertical sidewall. As mentioned above, because the hardness of the implanted hard mask layer 142 increases, the issue of the bit line BL wiggling may be reduced such that the sidewall BLS of the bit line BL is a vertical sidewall.

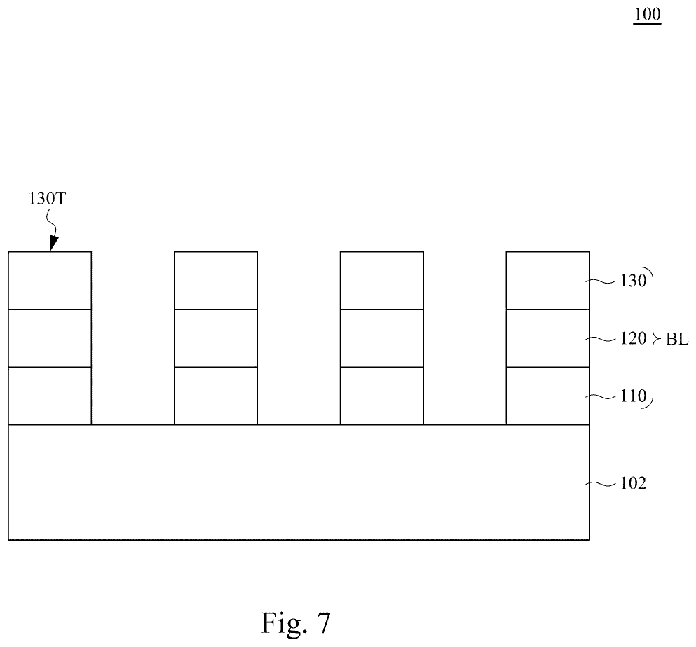

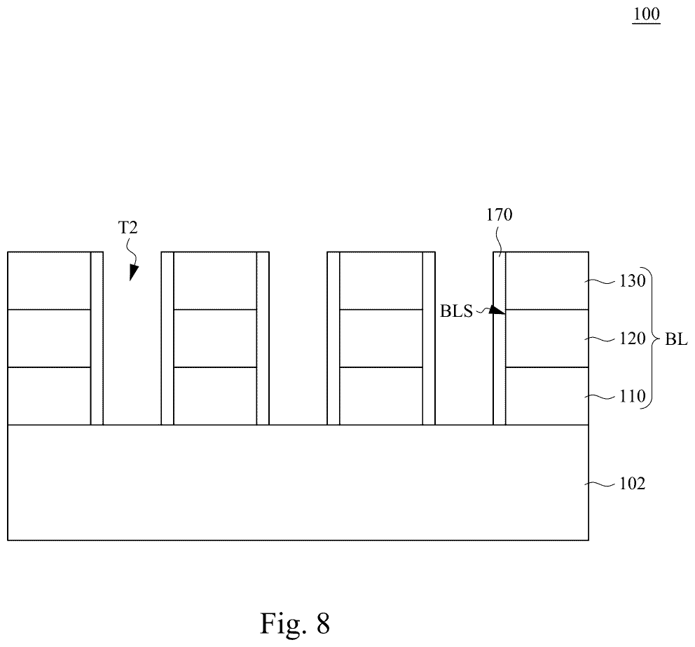

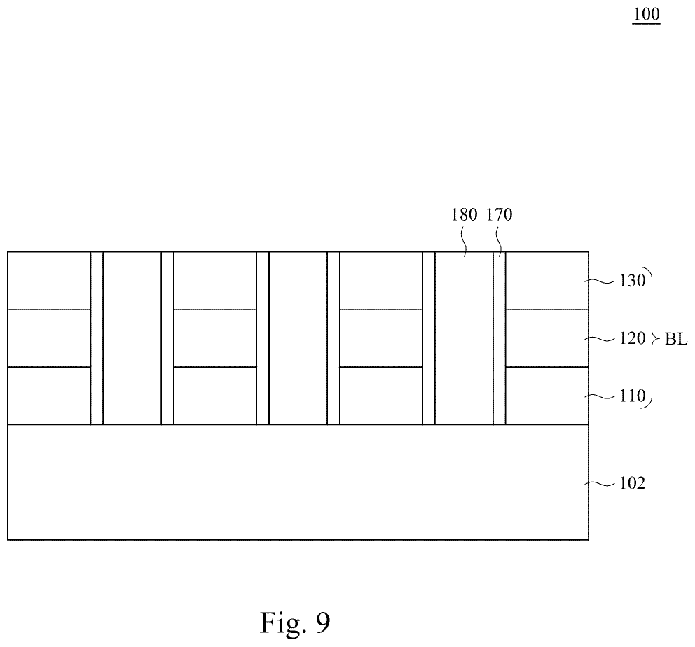

Referring to FIG. 7, the implanted hard mask layer 142 is removed to expose the top surface 130T of the second dielectric layer 130. Referring to FIG. 8, a spacer 170 can be formed on the sidewall BLS of the bit line BL. In some embodiments, the spacer 170 may include oxide or other suitable dielectric materials. In some embodiments, the spacer 170 can be single layer. In other embodiments, the spacer 170 can include multi-layers and may include an air gap in between. In some embodiments, the spacer 170 may be formed using a suitable deposition process, such as chemical vapor deposition (CVD), plasma enhanced chemical vapor deposition (PECVD), atomic layer deposition (ALD), or the like. Referring to FIG. 9, a filling layer 180 is formed to fill the second trench T2. In some embodiments, the filling layer 180 can include suitable isolation materials.

The present disclosure provides a manufacturing method of a semiconductor structure. By implanting nitrogen into the carbon hard mask of the bit line structure, the hardness of the hard mask can increase such that the bit line wiggling issue is reduced.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of manufacturing semiconductor structure, comprising:
providing a substrate;
forming a conductive layer on the substrate;
forming a dielectric layer on the conductive layer;
forming a hard mask layer on the dielectric layer, wherein the hard mask layer includes carbon;
performing an implantation process to implant nitrogen into the hard mask layer to form an implanted hard mask layer, wherein the implantation process is performed under a nitrogen dose of 1×10¹⁷ N⁺/cm² to 5×10¹⁷ N⁺/cm² and an implantation temperature of −200 °C to 600 °C;
forming a trench by removing a portion of the implanted hard mask layer, the dielectric layer and the conductive layer such that a top surface of the substrate is exposed, wherein a first angle between a top surface and a sidewall of the implanted hard mask remained 90 degree after forming a trench; and
removing the implanted hard mask layer to exposed the top surface of the dielectric layer, wherein the dielectric layer and the conductive layer collectively form a bit line structure in which a sidewall of the bit line structure is a vertical sidewall.

2. The method of claim 1, further comprising:
after performing the implantation process, forming a first additional mask on the implanted hard mask layer; and
forming a second additional mask on the first additional mask, wherein the first additional mask and the second additional mask comprise different materials.

3. The method of claim 1, wherein forming the dielectric layer comprises:
forming a first dielectric layer on the conductive layer; and
forming a second dielectric layer on the first dielectric layer, wherein the first dielectric layer and the second dielectric layer comprise different materials.

4. The method of claim 1, wherein the trench is formed by performing a dry etching process with CHF₃ and Ar at 15 °C.

5. The method of claim 1, wherein the implantation process is performed under the implantation temperature of −100 °C.

6. The method of claim 5, wherein the implantation process is performed under the nitrogen dose 2×10¹⁷ N⁺/cm².

7. The method of claim 6, wherein the implantation process is performed under an implantation voltage of 100 keV.

8. The method of claim 1, further comprising
forming a spacer on the sidewall of the bit line structure.

9. A method of manufacturing semiconductor structure, comprising:
providing a substrate;
forming a conductive layer on the substrate;
forming a dielectric layer on the conductive layer;
forming a hard mask layer on the dielectric layer, wherein the hard mask layer comprises SP²-bonded carbon and hydrogen hexagonal planar structure;
performing an implantation process to implant nitrogen into the hard mask layer to form an implanted hard mask layer, wherein the implanted hard mask layer comprises C₃N₄ with hexagonal network of tetrahedrally bonded carbon and trigonal planar nitrogen;
forming a trench by removing a portion of the implanted hard mask layer, the dielectric layer and the conductive layer such that a top surface of the substrate is exposed, wherein a first angle between a top surface and a sidewall of the implanted hard mask remained 90 degree after forming a trench; and
removing the implanted hard mask layer to exposed the top surface of the dielectric layer, wherein the dielectric layer and the conductive layer collectively form a bit line structure in which a sidewall of the bit line structure is a vertical sidewall.

10. The method of claim 9, wherein the implantation process is performed under a nitrogen dose of 1×10¹⁷ N⁺/cm² to 5×10¹⁷ N⁺/cm² and an implantation temperature of −200 °C to 600 °C.

11. The method of claim 10, wherein the implantation process is performed under the implantation temperature of −100 °C.

12. The method of claim 11, wherein the implantation process is performed under the nitrogen dose 2×10¹⁷ N⁺/cm².

13. The method of claim 12, wherein the implantation process is performed under an implantation voltage of 100 keV.

14. The method of claim 9, further comprising
forming a spacer on the sidewall of the bit line structure.

15. The method of claim 14, further comprising:
forming a filling layer to fill the trench.
